(19) United States
(12) Patent Application Publication
(10) Pub. No.: US 2026/0291514 A1
(43) Pub. Date: Sep. 24, 2026

(54) Analog-to-digital conversion apparatus and method having quick conversion mechanism

(71) Applicant: REALTEK SEMICONDUCTOR CORPORATION, HSINCHU (TW)

(72) Inventor: SHIH-HSIUNG HUANG, Hsinchu (TW)

(21) Appl. No.: 19/553,521

(22) Filed: Mar. 2, 2026

(30) Foreign Application Priority Data
Mar. 18, 2025 (TW) 114110167

(51) Int. Cl. H03M 1/12; H03M 1/36

(52) U.S. Cl. CPC H03M 1/1245; H03M 1/36

(57) ABSTRACT

An analog-to-digital conversion apparatus having a quick conversion mechanism is provided. A front stage sampling switch circuit is enabled in a front stage sampling enabling time interval to perform a sampling and hold process on an input analog signal to generate a front stage analog signal. A front stage quantization circuit quantizes the front stage analog signal to generate an N-bit quantization result. A back stage sampling switch circuit included by a back stage circuit is enabled in a back stage sampling enabling time interval to perform the sampling and hold process on the front stage analog signal to generate a back stage analog signal. An ADC circuit included by the back stage circuit sets the N-bit quantization result to be higher-bit conversion reference data to perform analog-to-digital conversion according to the higher-bit conversion reference data and the back stage analog signal to generate a digital signal.

### BACKGROUND OF THE INVENTION

### 1. Field of the Invention

The present invention relates to an analog-to-digital conversion apparatus and an analog-to-digital conversion method having a quick conversion mechanism.

### 2. Description of Related Art

An analog-to-digital conversion apparatus is to convert an analog signal in a continuous form to generate a digital signal in a discrete form. Some of the analog-to-digital conversion apparatuses perform conversion in a time-interleaved way and thus are implemented by a multi-layer circuit configuration. Between the circuits in different layers, signals are transmitted through switches and buffers that increase the conversion time of the analog-to-digital conversion apparatus.

### SUMMARY OF THE INVENTION

In consideration of the problem of the prior art, an object of the present invention is to supply an analog-to-digital conversion apparatus and an analog-to-digital conversion method having a quick conversion mechanism.

The present invention discloses an analog-to-digital conversion apparatus having a quick conversion mechanism that includes a front stage sampling switch circuit, a front stage quantization circuit, a back stage buffer circuit and a back stage circuit. The front stage sampling switch circuit is configured to be enabled in a front stage sampling enabling time interval to receive an input analog signal and perform a sampling and hold process on the input analog signal to generate a front stage analog signal. The front stage quantization circuit is configured to perform a front stage quantization on the front stage analog signal to generate an N-bit quantization result, wherein N is a positive number. The back stage circuit includes a back stage sampling switch circuit and an analog-to-digital conversion circuit. The back stage sampling switch circuit is electrically coupled to the front stage sampling switch circuit through the back stage buffer circuit so as to be enabled in a back stage sampling enabling time interval to receive the front stage analog signal through the back stage buffer circuit to perform the sampling and hold process to generate a back stage analog signal. The analog-to-digital conversion circuit is configured to receive the N-bit quantization result and the back stage analog signal to configure the N-bit quantization result to be higher-bit conversion reference data and perform an analog-to-digital conversion according to the higher-bit conversion reference data and the back stage analog signal to generate a digital signal.

The present invention also discloses an analog-to-digital conversion method having a quick conversion mechanism used in an analog-to-digital conversion apparatus that includes steps outlined below. A front stage sampling switch circuit is enabled in a front stage sampling enabling time interval to receive an input analog signal and perform a sampling and hold process on the input analog signal to generate a front stage analog signal. A front stage quantization is performed on the front stage analog signal by a front stage quantization circuit to generate an N-bit quantization result, wherein N is a positive number. A back stage sampling switch circuit included by a back stage circuit is electrically coupled to the front stage sampling switch circuit through a back stage buffer circuit so as to be enabled in a back stage sampling enabling time interval to receive the front stage analog signal through the back stage buffer circuit to perform the sampling and hold process to generate a back stage analog signal. The N-bit quantization result and the back stage analog signal are received by an analog-to-digital conversion circuit included by the back stage circuit to configure the N-bit quantization result to be higher-bit conversion reference data and perform an analog-to-digital conversion according to the higher-bit conversion reference data and the back stage analog signal to generate a digital signal.

These and other objectives of the present invention will no doubt become obvious to those of ordinary skill in the art behind reading the following detailed description of the preferred embodiments that are illustrated in the various figures and drawings.

### BRIEF DESCRIPTION OF THE DRAWINGS

FIG. 1A illustrates a circuit diagram of an analog-to-digital conversion apparatus having a quick conversion mechanism according to an embodiment of the present invention.

FIG. 1B illustrates a waveform diagram of a plurality of signals related to the operation of the analog-to-digital conversion apparatus according to an embodiment of the present invention.

FIG. 2A illustrates a circuit diagram of the front stage quantization circuit according to an embodiment of the present invention.

FIG. 2B illustrates a circuit diagram of the front stage quantization circuit according to another embodiment of the present invention.

FIG. 3A illustrates a circuit diagram of an analog-to-digital conversion apparatus having a quick conversion mechanism according to an embodiment of the present invention.

FIG. 3B illustrates a waveform diagram of a plurality of signals related to the operation of the analog-to-digital conversion apparatus according to an embodiment of the present invention.

FIG. 3C illustrates a waveform diagram of a plurality of signals related to the operation of the analog-to-digital conversion apparatus according to another embodiment of the present invention.

FIG. 4 illustrates a circuit diagram of two analog-to-digital conversion apparatuses and a front stage buffer circuit according to an embodiment of the present invention.

FIG. 5 illustrates a flow chart of an analog-to-digital conversion method having a quick conversion mechanism according to an embodiment of the present invention.

### DETAILED DESCRIPTION OF THE PREFERRED EMBODIMENTS

An aspect of the present invention is to provide an analog-to-digital conversion apparatus and an analog-to-digital conversion method having a quick conversion mechanism to perform a front stage quantization by using a front stage quantization circuit to provide a quantization result as a higher-bit conversion result to a back stage circuit such that the back stage circuit performs an analog-to-digital conversion according to save the conversion time of back stage circuit to accomplish the quick conversion mechanism.

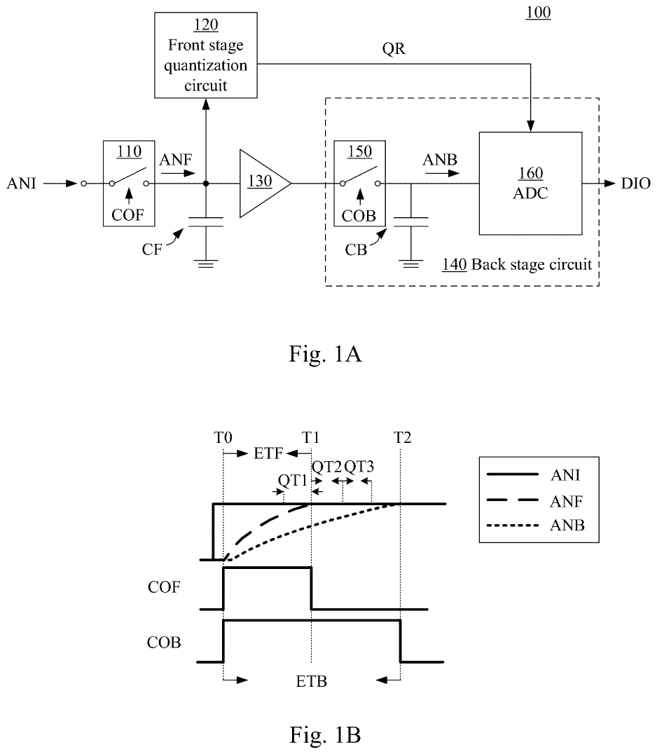

Reference is now made to FIG. 1A and FIG. 1B. FIG. 1A illustrates a circuit diagram of an analog-to-digital conversion apparatus 100 having a quick conversion mechanism according to an embodiment of the present invention. FIG. 1B illustrates a waveform diagram of a plurality of signals related to the operation of the analog-to-digital conversion apparatus 100 according to an embodiment of the present invention. In FIG. 1B, the X-axis represents the time, and the Y-axis represents the signal intensity.

The analog-to-digital conversion apparatus 100 includes a front stage sampling switch circuit 110, a front stage quantization circuit 120, a back stage buffer circuit 130 and a back stage circuit 140.

The front stage sampling switch circuit 110 is configured to be enabled in a front stage sampling enabling time interval ETF illustrated in FIG. 1B according to such as, but not limited to the control of a control signal COF to receive an input analog signal ANI and only perform a sampling and hold process to generate a front stage analog signal ANF. In the present embodiment, the control signal COF is at a high state in the front stage sampling enabling time interval ETF to keep the front stage sampling switch circuit 110 conducted to perform the sampling and hold process and is at a low state outside of the front stage sampling enabling time interval ETF to keep the front stage sampling switch circuit 110 unconducted to control the front stage quantization circuit 120 to stop receiving the input analog signal ANI.

The front stage sampling switch circuit 110 further transmits the front stage analog signal ANF to the back stage buffer circuit 130. In FIG. 1B, the input analog signal ANI is illustrated by a solid line and the front stage analog signal ANF is illustrated by a dashed line.

In an embodiment, a front stage capacitive effect, affecting a front stage stable state that the front stage analog signal ANF reaches, exists between the front stage sampling switch circuit 110 and the back stage buffer circuit 130. Such a front stage capacitive effect, as illustrated in FIG. 1A, is generated due to a capacitor CF located between the front stage sampling switch circuit 110 and the back stage buffer circuit 130. In different embodiments, the capacitor CF can be an actual capacitor or a parasitic capacitor between circuits. More specifically, the front stage capacitive effect can be generated according to an actual capacitor or a parasitic capacitor.

As a result, as illustrated in FIG. 1B, though a front stage sampling enabling initial point of the front stage sampling enabling time interval ETF corresponds to a time spot T0, the front stage analog signal ANF reaches the stable state at a front stage sampling enabling terminal point of the front stage sampling enabling time interval ETF corresponding to a time spot T1.

The front stage quantization circuit 120 is configured to perform a front stage quantization on the front stage analog signal ANF to generate N-bit quantization result QR, wherein N is a positive number.

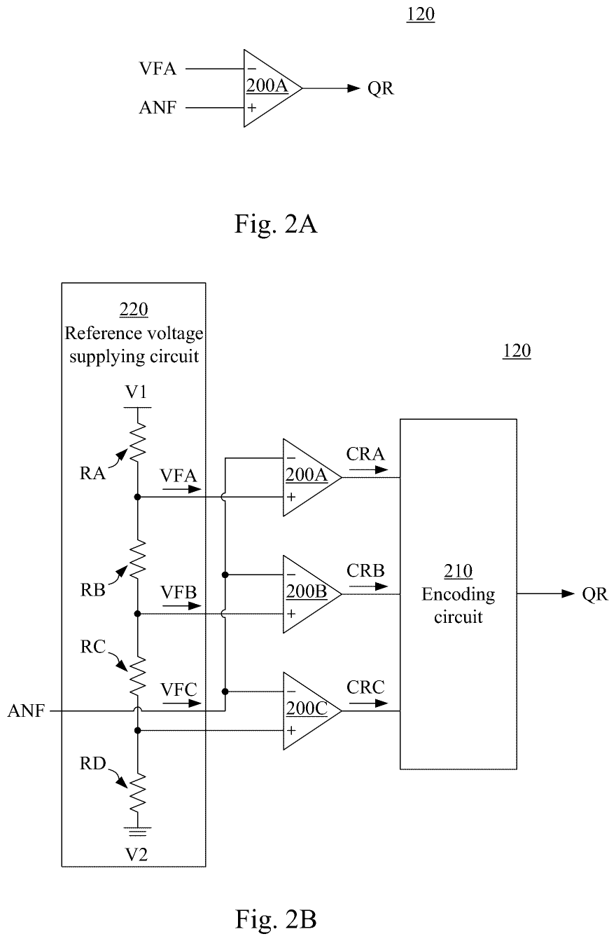

Reference is now made to FIG. 2A. FIG. 2A illustrates a circuit diagram of the front stage quantization circuit 120 according to an embodiment of the present invention. The front stage quantization circuit 120 includes a comparator 200A.

The comparator 200A is configured to receive the front stage analog signal ANF and a reference voltage VFA through two input terminals to generate a 1-bit quantization result QR (N is 1) at an output terminal.

In the present embodiment, the front stage analog signal ANF is in a single-ended form such that the comparator 200A compares the front stage analog signal ANF with the reference voltage VFA to generate the 1-bit quantization result QR. In other embodiments, when the front stage analog signal ANF is in a differential form, the comparator 200A compares two differential signals of the front stage analog signal ANF received through two input terminals to generate the 1-bit quantization result QR.

Reference is now made to FIG. 2B. FIG. 2B illustrates a circuit diagram of the front stage quantization circuit 120 according to another embodiment of the present invention. The front stage quantization circuit 120 includes comparators 200A~200C, an encoding circuit 210 and a reference voltage supplying circuit 220.

Each of the comparators 200A~200C receives and compares the front stage analog signal ANF with one of a plurality of reference voltages VFA~VFC to generate one of a plurality of comparison results CRA~CRC.

In the present embodiment, the reference voltages VFA~VFC are provided by the reference voltage supplying circuit 220. The reference voltage supplying circuit 220 includes resistors RA~RD electrically coupled between a first voltage V1 and a second voltage V2.

In an embodiment, the first voltage V1 is 1 volt and the second voltage V2 is 0 volt. The resistance of each of the resistors RA~RD is the same to generate the reference voltage VFA that is 0.75 volts between the resistors RA and RB, the reference voltage VFB that is 0.5 volts between the resistors RB and RC and the reference voltage VFC that is 0.25 volts between the resistors RC and RD.

As a result, the comparator 200A compares the front stage analog signal ANF with the reference voltage VFA to generate the comparison result CRA. The comparator 200B compares the front stage analog signal ANF with the reference voltage VFB to generate the comparison result CRB. The comparator 200C compares the front stage analog signal ANF with the reference voltage VFC to generate the comparison result CRC.

The encoding circuit 210 is configured to generate 2-bit quantization result according to the comparison results CRA~CRC. In an embodiment, the encoding circuit 210 may generate the 2-bit quantization result QR that includes D0 and D1 according to Table 1 shown below:

TABLE 1

| CRA | CRB | CRC | D0 | D1 |
|---|---|---|---|---|
| 1 | 1 | 1 | 0 | 0 |
| 1 | 1 | 0 | 0 | 1 |
| 1 | 0 | 0 | 1 | 0 |
| 0 | 0 | 0 | 1 | 1 |

It is appreciated that the number of the bit and the values described above are merely an example. The present invention is not limited thereto. In other embodiments, the front stage quantization circuit 120 may include different numbers of comparators and reference voltages to generate the N-bit quantization result, in which Nis any number that is larger than 1. Further, in different embodiments, N can be an integer or a non-integer. For example, in some configurations, the front stage quantization circuit 120 may generate the quantization result QR that is such as, but not limited to 1.5 bits, 2.5 bits or other bits.

Reference is now made to FIG. 1A again. The back stage circuit 140 includes a back stage sampling switch circuit 150 and an analog-to-digital conversion circuit 160 (abbreviated as ADC in FIG. 1A).

The back stage sampling switch circuit 150 is electrically coupled to the front stage sampling switch circuit 110 through the back stage buffer circuit 130, so as to be enabled in a back stage sampling enabling time interval ETB illustrated in FIG. 1B, according to such as but not limited to the control of the control signal COB, to receive the front stage analog signal ANF through the back stage buffer circuit 130 to perform a sampling and hold process to generate a back stage analog signal ANB. In the present embodiment, the control signal COB is at a high state in the back stage sampling enabling time interval ETB to keep the back stage sampling switch circuit 150 conducted to perform the sampling and hold process and is at a low state outside of the back stage sampling enabling time interval ETB to keep the back stage sampling switch circuit 150 unconducted such that the analog-to-digital conversion circuit 160 stops to receive the back stage analog signal ANB.

The back stage sampling switch circuit 150 further transmits the back stage analog signal ANB to the analog-to-digital conversion circuit 160. In FIG. 1B, the back stage analog signal ANB is illustrated by a dotted line.

In an embodiment, a back stage capacitive effect, affecting a back stage stable state that the back stage analog signal ANB reaches, exists between the back stage sampling switch circuit 150 and the analog-to-digital conversion circuit 160. Such a back stage capacitive effect, as illustrated in FIG. 1A, is generated due to a capacitor CB located between the back stage sampling switch circuit 150 and the analog-to-digital conversion circuit 160. In different embodiments, the capacitor CB can be an actual capacitor or a parasitic capacitor between circuits. More specifically, the back stage capacitive effect can be generated according to an actual capacitor or a parasitic capacitor.

As a result, as illustrated in FIG. 1B, though a back stage sampling enabling initial point of the back stage sampling enabling time interval ETB also corresponds to the time spot T0, which is the same as the front stage sampling enabling initial point, the back stage analog signal ANB reaches the stable state at a back stage sampling enabling terminal point of the back stage sampling enabling time interval ETB corresponding to a time spot T2.

As described above, in the present embodiment, the back stage sampling enabling initial point of the back stage sampling enabling time interval ETB and the front stage sampling enabling initial point both correspond to the time spot T0. Further, in the present embodiment, the back stage sampling enabling time interval ETB and the front stage sampling enabling time interval ETF are partially overlapped, and the time spot T2 that the back stage sampling enabling terminal point of the back stage sampling enabling time interval ETB corresponds to is later than the time spot T1 that the front stage sampling enabling terminal point of the front stage sampling enabling time interval corresponds to.

The analog-to-digital conversion circuit 160 is configured to receive the N-bit quantization result QR and the back stage analog signal ANB to configure the N-bit quantization result QR to be higher-bit conversion reference data and perform an analog-to-digital conversion according to the higher-bit conversion reference data and the back stage analog signal ANB to generate a digital signal DIO.

In an embodiment, the analog-to-digital conversion circuit 160 can be a non-redundancy configuration. Under the non-redundancy configuration, the analog-to-digital conversion circuit 160 may directly configure the higher-bit conversion reference data (i.e., the N-bit quantization result QR) to be a highest N-bit conversion result to perform the analog-to-digital conversion according to the highest N-bit conversion result and the back stage analog signal ANB to generate the digital signal DIO.

In an embodiment, the analog-to-digital conversion circuit 160 operates according to a successive approximation mechanism to switch bit capacitors therein having different capacitances arranged from the largest value to the smallest value to modify the voltage inputted thereto. According to the N-bit quantization result QR, the analog-to-digital conversion circuit 160, by using the control circuit therein, directly switches the capacitors corresponding to the highest N bits without performing comparison and subsequently performs the successive approximation mechanism to switch the capacitors corresponding to the lower bits to perform comparison on the voltage inputted thereto to generate the lower-bit conversion result.

Furthermore, according to the type and the configuration of the analog-to-digital conversion circuit 160, the analog-to-digital conversion circuit 160 may perform subsequent processing on the highest N-bit conversion result and the lower-bit conversion result to generate the digital signal DIO.

In an embodiment, the analog-to-digital conversion circuit 160 can be a redundancy configuration. Under the redundancy configuration, the analog-to-digital conversion circuit 160 may perform a redundancy calculation according to the higher-bit conversion reference data (i.e., the N-bit quantization result QR) to generate a redundancy calculation result to perform the analog-to-digital conversion according to the redundancy calculation result and the back stage analog signal to generate the digital signal DIO. The redundancy configuration of the analog-to-digital conversion circuit 160 and the performance of the redundancy calculation can be implemented by any possible technologies and are not described herein.

Similarly, the analog-to-digital conversion circuit 160 may operate according to the successive approximation mechanism to switch the capacitors to obtain the conversion result of all the bits according to the redundancy calculation result and the back stage analog signal (e.g., Q bits that are larger than N) to generate the digital signal DIO.

As a result, the time that the analog-to-digital conversion circuit 160 performs the analog-to-digital conversion may be shortened according to the information of the N-bit quantization result QR to greatly increase the efficiency of the analog-to-digital conversion.

In an embodiment, according to the timings of FIG. 1B, the front stage quantization circuit 120 performs the front stage quantization in at least one of a first quantization time QT1, a second quantization time QT2 and a third quantization time QT3 illustrated in FIG. 1B. The first quantization time QT1 corresponds to a terminal section of the front stage sampling enabling time interval ETF. The second quantization time QT2 corresponds to a neighboring section later than and neighboring to the front stage sampling enabling time interval ETF. The third quantization time QT3 corresponds to a distancing section later than and having a distance from the front stage sampling enabling time interval ETF.

Preferably, the first quantization time QT1, the second quantization time QT2 and the third quantization time QT3 of the back stage sampling enabling time interval ETB are ahead of the back stage sampling enabling terminal point (which is the time spot T2). In the quantization times described above, the front stage analog signal ANF that is quantized in the quantization time that is closer to the back stage sampling enabling terminal point is more stable. The quantization performed in the quantization time that is more ahead of the back stage sampling enabling terminal point allows the analog-to-digital conversion circuit 160 to save more time.

In different embodiments, the front stage quantization circuit 120 may perform quantization in any one of the quantization times depending on practical requirements.

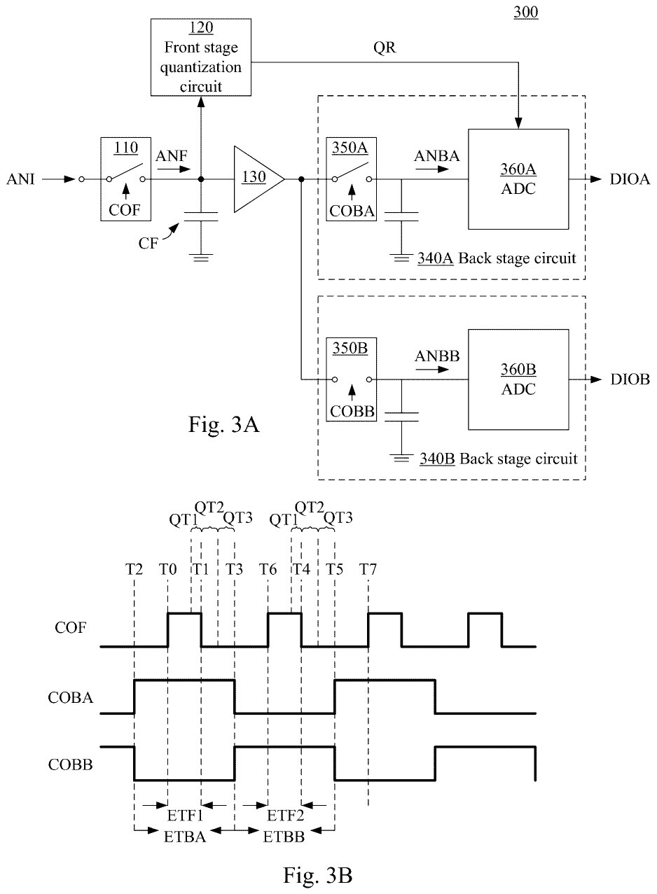

Reference is now made to FIG. 3A and FIG. 3B. FIG. 3A illustrates a circuit diagram of an analog-to-digital conversion apparatus 300 having a quick conversion mechanism according to an embodiment of the present invention. FIG. 3B illustrates a waveform diagram of a plurality of signals related to the operation of the analog-to-digital conversion apparatus 300 according to an embodiment of the present invention. In FIG. 3B, the X-axis represents the time, and the Y-axis represents the signal intensity.

As illustrated in FIG. 3A, the analog-to-digital conversion apparatus 300, similar to the analog-to-digital conversion apparatus 100, includes the front stage sampling switch circuit 110, the front stage quantization circuit 120 and the back stage buffer circuit 130. The configuration and the operation of these circuits are not described herein.

In the present embodiment, the analog-to-digital conversion apparatus 300 includes two back stage circuits 340A and 340B, both being electrically coupled to the back stage buffer circuit 130. The back stage circuit 340A includes a back stage sampling switch circuit 350A and an analog-to-digital conversion circuit 360A (abbreviated as ADC in FIG. 3A). The back stage circuit 340B includes a back stage sampling switch circuit 350B and an analog-to-digital conversion circuit 360B (abbreviated as ADC in FIG. 3A). The connection relations of the components in the two back stage circuits 340A and 340B are the same as those in the back stage circuit 140 in FIG. 1A and are not described herein.

In FIG. 3B, the front stage analog signal ANF generated by the front stage sampling switch circuit 110 and the back stage analog signals ANBA and ANBB generated by the back stage sampling switch circuits 350A and 350B are not illustrated. Only the control signal COF to control the front stage sampling switch circuit 110 and the control signals COBA and COBB to control the back stage sampling switch circuit 350A and 350B are exemplarily illustrated.

The front stage sampling switch circuit 110 is enabled in the front stage sampling enabling time interval ETF1 illustrated in FIG. 3B. The front stage sampling enabling initial point of the front stage sampling enabling time interval ETF1 corresponds to the time spot T0 and the front stage sampling enabling terminal point of the front stage sampling enabling time interval ETF1 corresponds to the time spot T1.

Corresponding to the front stage sampling enabling time interval ETF1, the back stage sampling switch circuit 350A is enabled in the back stage sampling enabling time interval ETBA illustrated in FIG. 3B. The back stage sampling enabling initial point of the back stage sampling enabling time interval ETBA corresponds to the time spot T2 and the back stage sampling enabling terminal point of the back stage sampling enabling time interval ETBA corresponds to the time spot T3.

The front stage sampling switch circuit 110 is enabled in the front stage sampling enabling time interval ETF2 illustrated in FIG. 3B again. The front stage sampling enabling initial point of the front stage sampling enabling time interval ETF2 corresponds to the time spot T6 and the front stage sampling enabling terminal point of the front stage sampling enabling time interval ETF2 corresponds to the time spot T4.

Corresponding to the front stage sampling enabling time interval ETF2, the back stage sampling switch circuit 350B is enabled in the back stage sampling enabling time interval ETBB illustrated in FIG. 3B. The back stage sampling enabling initial point of the back stage sampling enabling time interval ETBB corresponds to the time spot T3 and the back stage sampling enabling terminal point of the back stage sampling enabling time interval ETBB corresponds to the time spot T5.

As a result, the two back stage sampling enabling time intervals ETBA and ETBB that the back stage circuits 340A and 340B correspond to are interlaced without overlapping each other to allow the back stage circuits 340A and 340B to together form a time-interleaved analog-to-digital conversion circuit. The analog-to-digital conversion circuits 360A and 360B respectively generate the digital signals DIOA and DIOB. The analog-to-digital conversion apparatus 300 may selectively include a circuit that combines the digital signals DIOA and DIOB.

Further, in the present embodiment, the back stage sampling enabling time interval ETBA and the front stage sampling enabling time interval ETF1 are partially overlapped. The back stage sampling enabling initial point of the back stage sampling enabling time interval ETBA (i.e., the time spot T2) is ahead of the front stage sampling enabling initial point of the front stage sampling enabling time interval ETF1 (i.e., the time spot T0). The back stage sampling enabling terminal point of the back stage sampling enabling time interval ETBA (i.e., the time spot T3) is later than the front stage sampling enabling terminal point of the front stage sampling enabling time interval ETF1 (i.e., the time spot T1). The front stage sampling enabling time interval ETF1 is thus completely within the range of the back stage sampling enabling time interval ETBA.

On the other hand, the back stage sampling enabling time interval ETBB and the front stage sampling enabling time interval ETF2 are partially overlapped. The back stage sampling enabling initial point of the back stage sampling enabling time interval ETBB (i.e., the time spot T3) is ahead of the front stage sampling enabling initial point of the front stage sampling enabling time interval ETF2 (i.e., the time spot T6). The back stage sampling enabling terminal point of the back stage sampling enabling time interval ETBB (i.e., the time spot T5) is later than the front stage sampling enabling terminal point of the front stage sampling enabling time interval ETF2 (i.e., the time spot T4). The front stage sampling enabling time interval ETF2 is thus completely within the range of the back stage sampling enabling time interval ETBB.

Reference is now made to FIG. 3C. FIG. 3C illustrates a waveform diagram of a plurality of signals related to the operation of the analog-to-digital conversion apparatus 300 according to another embodiment of the present invention. In FIG. 3C, the X-axis represents the time, and the Y-axis represents the signal intensity.

Similar to FIG. 3B, the control signal COF, the control signals COBA and COBB and the related time intervals, e.g., the front stage sampling enabling time intervals ETF1 and ETF2 and the back stage sampling enabling time intervals ETBA and ETBB are illustrated in FIG. 3C. In FIG. 3C, the back stage sampling enabling time intervals ETBA and ETBB are also interlaced without overlapping each other to allow the back stage circuits 340A and 340B to together form a time-interleaved analog-to-digital conversion circuit.

However, the difference between FIG. 3C and FIG. 3B is that the back stage sampling enabling time interval ETBA and the front stage sampling enabling time interval ETF1 are not overlapped in FIG. 3C, and the back stage sampling enabling time interval ETBA is later than the front stage sampling enabling time interval ETF1 in FIG. 3C. Further, the back stage sampling enabling time interval ETBB and the front stage sampling enabling time interval ETF2 are not overlapped in FIG. 3C, and the back stage sampling enabling time interval ETBB is later than the front stage sampling enabling time interval ETF2 in FIG. 3C.

In an embodiment, according to the timings in FIG. 3B and FIG. 3C and taking the front stage sampling enabling time interval ETF1 as an example, the front stage quantization circuit 120 performs the front stage quantization in at least one of the first quantization time QT1, the second quantization time QT2 and the third quantization time QT3 in FIG. 3B and FIG. 3C. The definition of these quantization times are the same as those described above and is not described herein.

By using the configurations and the timings described above, the back stage circuits 340A and 340B in the analog-to-digital conversion apparatus 300 together form the time-interleaved analog-to-digital conversion circuit, in which the back stage circuits 340A and 340B can accomplish the quick conversion mechanism by using the configuration of the front stage quantization circuit 120. It is appreciated that the number of the back stage circuits illustrated in FIG. 3A is merely an example. In other embodiments, the number of the back stage circuit is M, wherein M is a positive integer that is larger than 1.

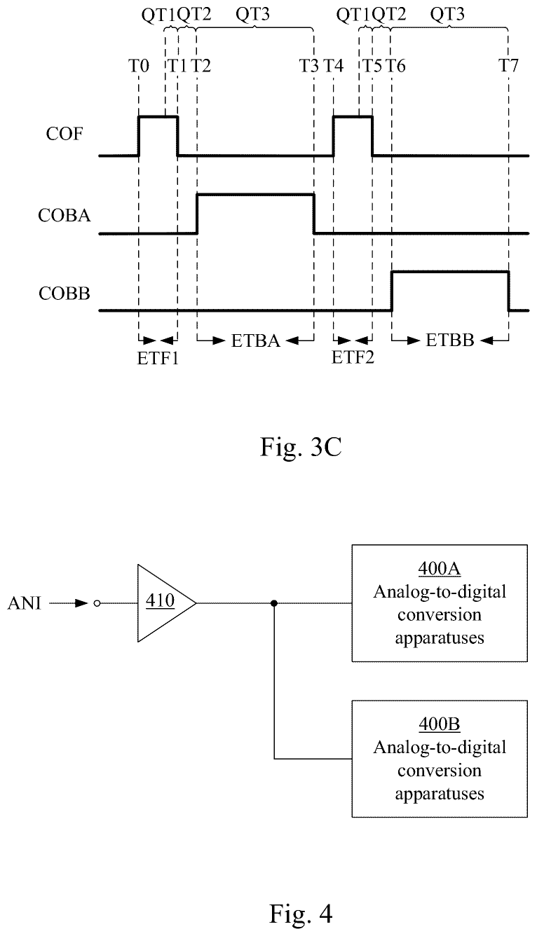

Reference is now made to FIG. 4. FIG. 4 illustrates a circuit diagram of two analog-to-digital conversion apparatuses 400A and 400B and a front stage buffer circuit 410 according to an embodiment of the present invention.

The configuration and operation of each of the analog-to-digital conversion apparatuses 400A and 400B can be identical to the analog-to-digital conversion apparatus 100 in FIG. 1A or the analog-to-digital conversion apparatus 300 in FIG. 3A and are not described herein. The analog-to-digital conversion apparatuses 400A and 400B are both electrically coupled to the front stage buffer circuit 410 and receive the input analog signal ANI through the front stage buffer circuit 410 to together form a time-interleaved analog-to-digital conversion apparatus.

More specifically, the analog-to-digital conversion apparatuses 400A and 400B operate the front stage sampling switch circuits therein in a time-interleaved manner to receive the input analog signal ANI through the front stage buffer circuit 410 in turn to perform the analog-to-digital conversion. When each of the analog-to-digital conversion apparatuses 400A and 400B is implemented by the analog-to-digital conversion apparatus 300 in FIG. 3A, the back stage circuits included therein can further perform the analog-to-digital conversion in turn.

Moreover, each of the analog-to-digital conversion apparatuses 400A and 400B can accomplish the quick conversion mechanism by using the front stage quantization circuits therein. It is appreciated that the number of the analog-to-digital conversion apparatuses 400A and 400B illustrated in FIG. 4 is merely an example. In other embodiments, the number of the analog-to-digital conversion apparatuses can be P, wherein P is a positive integer that is larger than 1.

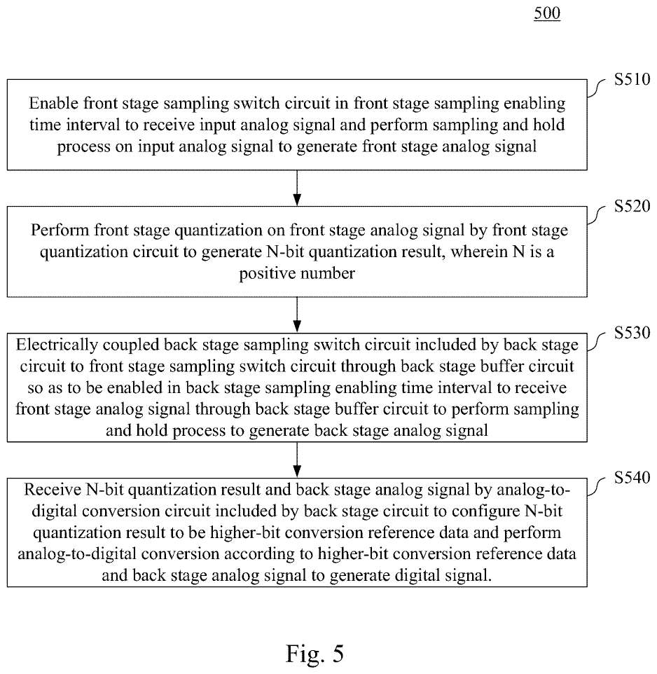

Reference is now made to FIG. 5. FIG. 5 illustrates a flow chart of an analog-to-digital conversion method 500 having a quick conversion mechanism according to an embodiment of the present invention.

In addition to the apparatus described above, the present disclosure further provides the analog-to-digital conversion method 500 having the quick conversion mechanism that can be used in such as, but not limited to, the analog-to-digital conversion apparatus 100 in FIG. 1A or the analog-to-digital conversion apparatus 300 in FIG. 3A. As illustrated in FIG. 5, an embodiment of the analog-to-digital conversion method 500 includes the following steps.

In step S510, the front stage sampling switch circuit 110 is enabled in the front stage sampling enabling time interval ETF to receive the input analog signal ANI and perform the sampling and hold process on the input analog signal ANI to generate the front stage analog signal ANF.

In step S520, the front stage quantization is performed on the front stage analog signal ANF by the front stage quantization circuit 120 to generate the N-bit quantization result QR, wherein N is a positive number.

In step S530, the back stage sampling switch circuit 150 included by the back stage circuit 140 is electrically coupled to the front stage sampling switch circuit 110 through the back stage buffer circuit 130 so as to be enabled in the back stage sampling enabling time interval ETB to receive the front stage analog signal ANF through the back stage buffer circuit 130 to perform the sampling and hold process to generate the back stage analog signal ANB.

In step S540, the N-bit quantization result QR and the back stage analog signal ANB are received by the analog-to-digital conversion circuit 160 included by the back stage circuit 140 to configure the N-bit quantization result QR to be the higher-bit conversion reference data and perform the analog-to-digital conversion according to the higher-bit conversion reference data and the back stage analog signal ANB to generate the digital signal DIO.

In summary, the present invention discloses the analog-to-digital conversion apparatus and the analog-to-digital conversion method having the quick conversion mechanism

The aforementioned descriptions represent merely the preferred embodiments of the present invention, without any intention to limit the scope of the present invention thereto. Various equivalent changes, alterations, or modifications based on the claims of present invention are all consequently viewed as being embraced by the scope of the present invention.

What is claimed is:

1. An analog-to-digital conversion apparatus having a quick conversion mechanism, comprising:
a front stage sampling switch circuit configured to be enabled in a front stage sampling enabling time interval to receive an input analog signal and perform a sampling and hold process on the input analog signal to generate a front stage analog signal;
a front stage quantization circuit configured to perform a front stage quantization on the front stage analog signal to generate an N-bit quantization result, wherein N is a positive number;
a back stage buffer circuit; and
a back stage circuit comprising:
a back stage sampling switch circuit to be electrically coupled to the front stage sampling switch circuit through the back stage buffer circuit so as to be enabled in a back stage sampling enabling time interval to receive the front stage analog signal through the back stage buffer circuit to perform the sampling and hold process to generate a back stage analog signal; and
an analog-to-digital conversion circuit configured to receive the N-bit quantization result and the back stage analog signal to configure the N-bit quantization result to be higher-bit conversion reference data and perform an analog-to-digital conversion according to the higher-bit conversion reference data and the back stage analog signal to generate a digital signal.

2. The analog-to-digital conversion apparatus of claim 1, wherein the analog-to-digital conversion circuit directly configures the higher-bit conversion reference data to be a highest N-bit conversion result in a non-redundancy configuration to perform the analog-to-digital conversion according to the highest N-bit conversion result and the back stage analog signal to generate the digital signal; and
the analog-to-digital conversion circuit performs a redundancy calculation according to the higher-bit conversion reference data in a redundancy configuration to generate a redundancy calculation result to perform the analog-to-digital conversion according to the redundancy calculation result and the back stage analog signal to generate the digital signal.

3. The analog-to-digital conversion apparatus of claim 1, wherein a front stage capacitive effect, affecting a front stage stable state that the front stage analog signal reaches, exists between the front stage sampling switch circuit and the back stage buffer circuit, and a back stage capacitive effect, affecting a back stage stable state that the back stage analog signal reaches, exists between the back stage sampling switch circuit and the analog-to-digital conversion circuit;
wherein each of the front stage capacitive effect and the back stage capacitive effect is generated according to an actual capacitor or a parasitic capacitor.

4. The analog-to-digital conversion apparatus of claim 1, wherein the back stage sampling enabling time interval and the front stage sampling enabling time interval are partially overlapped, and a back stage sampling enabling terminal point of the back stage sampling enabling time interval is later than a front stage sampling enabling terminal point of the front stage sampling enabling time interval.

5. The analog-to-digital conversion apparatus of claim 1, wherein the back stage sampling enabling time interval and the front stage sampling enabling time interval are not overlapped, and the back stage sampling enabling time interval is later than the front stage sampling enabling time interval.

6. The analog-to-digital conversion apparatus of claim 1, wherein the front stage quantization circuit performs the front stage quantization in at least one of a first quantization time, a second quantization time and a third quantization time, the first quantization time corresponds to a terminal section of the front stage sampling enabling time interval, the second quantization time corresponds to a neighboring section later than and neighboring to the front stage sampling enabling time interval and the third quantization time corresponds to a distancing section later than and having a distance from the front stage sampling enabling time interval;
wherein the first quantization time, the second quantization time and the third quantization time are in front of a back stage sampling enabling terminal point of the back stage sampling enabling time interval.

7. The analog-to-digital conversion apparatus of claim 1, wherein a number of the back stage circuit is M, and the M back stage circuits are all electrically coupled to the back stage buffer circuit, and the M back stage sampling enabling time intervals that the M back stage circuits correspond to are interlaced without overlapping with each other to together form a time-interleaved analog-to-digital conversion circuit, wherein M is a positive integer that is larger than 1.

8. The analog-to-digital conversion apparatus of claim 1, the front stage quantization circuit comprises:
a plurality of comparators each to receive the front stage analog signal to compare the front stage analog signal with one of a plurality of reference voltages to generate one of a plurality of comparison results; and
an encoding circuit configured to generate the N-bit quantization result according to the comparison results, wherein N is larger than 1.

9. The analog-to-digital conversion apparatus of claim 1, the front stage quantization circuit comprises:
a comparison circuit configured to receive the front stage analog signal in a single-ended form to compare the front stage analog signal with a reference voltage to generate the N-bit quantization result, or receive the front stage analog signal in a differential form to compare two differential signals of the front stage analog signal to generate the N-bit quantization result, wherein N is larger than 1.

10. The analog-to-digital conversion apparatus of claim 1, wherein a number of the analog-to-digital conversion apparatus is P, the P analog-to-digital conversion apparatuses are all electrically coupled to a front stage buffer circuit so as to receive the input analog signal through the front stage buffer circuit to together form a time-interleaved analog-to-digital conversion apparatus, wherein P is a positive integer that is larger than 1.

11. An analog-to-digital conversion method having a quick conversion mechanism used in an analog-to-digital conversion apparatus, comprising:
enabling a front stage sampling switch circuit in a front stage sampling enabling time interval to receive an input analog signal and perform a sampling and hold process on the input analog signal to generate a front stage analog signal;
performing a front stage quantization on the front stage analog signal by a front stage quantization circuit to generate an N-bit quantization result, wherein N is a positive number;
electrically coupling a back stage sampling switch circuit comprised by a back stage circuit to the front stage sampling switch circuit through a back stage buffer circuit so as to enable the back stage sampling switch circuit in a back stage sampling enabling time interval to receive the front stage analog signal through the back stage buffer circuit to perform the sampling and hold process to generate a back stage analog signal; and
receiving the N-bit quantization result and the back stage analog signal by an analog-to-digital conversion circuit comprised by the back stage circuit to configure the N-bit quantization result to be higher-bit conversion reference data and perform an analog-to-digital conversion according to the higher-bit conversion reference data and the back stage analog signal to generate a digital signal.

12. The analog-to-digital conversion method of claim 11, further comprising:
directly configuring the higher-bit conversion reference data to be a highest N-bit conversion result in a non-redundancy configuration by the analog-to-digital conversion circuit to perform the analog-to-digital conversion according to the highest N-bit conversion result and the back stage analog signal to generate the digital signal; and
performing a redundancy calculation according to the higher-bit conversion reference data in a redundancy configuration by the analog-to-digital conversion circuit to generate a redundancy calculation result to perform the analog-to-digital conversion according to the redundancy calculation result and the back stage analog signal to generate the digital signal.

13. The analog-to-digital conversion method of claim 11, wherein a front stage capacitive effect, affecting a front stage stable state that the front stage analog signal reaches, exists between the front stage sampling switch circuit and the back stage buffer circuit, and a back stage capacitive effect, affecting a back stage stable state that the back stage analog signal reaches, exists between the back stage sampling switch circuit and the analog-to-digital conversion circuit;
wherein each of the front stage capacitive effect and the back stage capacitive effect is generated according to an actual capacitor or a parasitic capacitor.

14. The analog-to-digital conversion method of claim 11, wherein the back stage sampling enabling time interval and the front stage sampling enabling time interval are partially overlapped, and a back stage sampling enabling terminal point of the back stage sampling enabling time interval is later than a front stage sampling enabling terminal point of the front stage sampling enabling time interval.

15. The analog-to-digital conversion method of claim 11, wherein the back stage sampling enabling time interval and the front stage sampling enabling time interval are not overlapped, and the back stage sampling enabling time interval is later than the front stage sampling enabling time interval.

16. The analog-to-digital conversion method of claim 11, further comprising:
performing the front stage quantization in at least one of a first quantization time, a second quantization time and a third quantization time by the front stage quantization circuit,
wherein the first quantization time corresponds to a terminal section of the front stage sampling enabling time interval, the second quantization time corresponds to a neighboring section later than and neighboring to the front stage sampling enabling time interval and the third quantization time corresponds to a distancing section later than and having a distance from the front stage sampling enabling time interval; and
wherein the first quantization time, the second quantization time and the third quantization time are in front of a back stage sampling enabling terminal point of the back stage sampling enabling time interval.

17. The analog-to-digital conversion method of claim 11, wherein a number of the back stage circuit is M, and the M back stage circuits are all electrically coupled to the back stage buffer circuit, and the M back stage sampling enabling time intervals that the M back stage circuits correspond to are interlaced without overlapping with each other to together form a time-interleaved analog-to-digital conversion circuit, wherein M is a positive integer that is larger than 1.

18. The analog-to-digital conversion method of claim 11, further comprising:
receiving the front stage analog signal by each of a plurality of comparators comprised by the front stage quantization circuit to compare the front stage analog signal with one of a plurality of reference voltages to generate one of a plurality of comparison results; and
generating the N-bit quantization result according to the comparison results by an encoding circuit comprised by the front stage quantization circuit, wherein N is larger than 1.

19. The analog-to-digital conversion method of claim 11, further comprising:
receiving the front stage analog signal in a single-ended form by a comparison circuit comprised by the front stage quantization circuit to compare the front stage analog signal with a reference voltage to generate the N-bit quantization result, or receiving the front stage analog signal in a differential form by the comparison circuit to compare two differential signals of the front stage analog signal to generate the N-bit quantization result, wherein N is larger than 1.

20. The analog-to-digital conversion method of claim 11, wherein a number of the analog-to-digital conversion apparatus is P, the P analog-to-digital conversion apparatuses are all electrically coupled to a front stage buffer circuit so as to receive the input analog signal through the front stage buffer circuit to together form a time-interleaved analog-to-digital conversion apparatus, wherein P is a positive integer that is larger than 1.
